(19) United States
(12) Patent Application Publication
(10) Pub. No.: US 2011/0234276 A1
(43) Pub. Date: Sep. 29, 2011

(54) VOLTAGE-CURRENT CONVERTER CIRCUIT AND PLL CIRCUIT HAVING THE SAME

(75) Inventor: Masaaki Kaneko, Yokohama-Shi (JP)

(73) Assignee: KABUSHIKI KAISHA TOSHIBA, Tokyo (JP)

(21) Appl. No.: 13/053,358

(22) Filed: Mar. 22, 2011

(30) Foreign Application Priority Data
Mar. 24, 2010 (JP) 2010-68054

(51) Int. Cl. H03L 7/08; H02M 11/00

(52) U.S. Cl. 327/157; 327/103

(57) ABSTRACT

According to an embodiment, a voltage-current converter circuit includes a first current mirror circuit, a first transistor, a variable resistor, a second transistor and a first current output unit. The first current mirror circuit includes a first conductivity type transistor supplied with a first voltage, and the first current mirror circuit is configured to produce a second electric current based on a first electric current. The first transistor has a second conductivity type, and the first electric current flows through the first transistor. One end of the variable resistor is connected to a source of the first transistor, the other end of the variable resistor is supplied with a second voltage, and a resistance value of the variable resistor changes depending on an input control voltage. The second transistor has the second conductivity type, and the second electric current flows through the second transistor. A drain and a gate of the second transistor are connected to the gate of the first transistor, and a source of the second transistor is supplied with the second voltage. The second transistor is configured such that a ratio W/L, a ratio of a gate width W to a gate length L, is smaller than a ratio W/L of the first transistor. The first current output unit is configured to output an output current based on the first electric current or the second electric current.

### CROSS REFERENCE TO RELATED APPLICATIONS

This application is based upon and claims the benefit of priority from the prior Japanese Patent Application No. 2010-68054 filed on Mar. 24, 2010 in Japan, the entire contents of which are incorporated herein by reference.

### FIELD

Embodiments described herein relate generally to a voltage-current converter circuit and a PLL circuit having the same.

### BACKGROUND

A voltage-current converter circuit is a circuit having an output current which increases as a control voltage increases (for example, refer to Amr M. Fahim, “Clock Generators for SOC Processors”, Springer, 2005, p. 45). The output current becomes a maximum value when the control voltage is equal to the power supply voltage. In the voltage-current converter circuit of the related art, the maximum value of the output current largely depends on the power supply voltage. For this reason, problems occur in circuits using such a voltage-current converter circuit when the power supply voltage varies.

For example, description will be made for a phase locked loop (PLL) circuit using such a voltage-current converter circuit. The PLL circuit includes a voltage controlled oscillator (VCO) having an oscillation frequency which varies depending on the control voltage from a low-pass filter. The VCO includes a voltage-current converter circuit which converts the control voltage from the low-pass filter into an electric current. The VCO further includes a current controlled oscillator having an oscillation frequency which varies depending on that electric current. For example, the oscillation frequency of the current controlled oscillator increases as the aforementioned electric current increases. As described above, since the output current of the voltage-current converter circuit is maximized when the control voltage is equal to the power supply voltage, the VCO at this moment oscillates at a maximum oscillation frequency.

In such a PLL circuit, since the maximum output current of the voltage-current converter circuit significantly depends on the power supply voltage, the maximum oscillation frequency of the VCO also significantly depends on the power supply voltage.

In other words, during a low power supply voltage, since the maximum value of the output current of the voltage-current converter circuit is excessively reduced, the maximum oscillation frequency of the VCO becomes lower than a desired frequency. Therefore, the PLL circuit may not be locked at the desired frequency.

Conversely, during a high power supply voltage, since the maximum value of the output current of the voltage-current converter circuit excessively increases, the maximum oscillation frequency of the VCO remarkably increases to be over the desired frequency. For this reason, as the control voltage increases, the oscillation frequency of the VCO exceeds an operable frequency of a divider provided in the next stage to the VCO, and the divider may not perform a normal operation. Therefore, the PLL circuit may erroneously operate.

### BRIEF DESCRIPTION OF THE DRAWINGS

FIG. 1 is a circuit diagram illustrating a voltage-current converter circuit according to a comparative example.

FIG. 2 is a plot illustrating voltage-current characteristics of the voltage-current converter circuit according to the comparative example.

FIG. 3 is a circuit diagram illustrating a GM-constant bias circuit in a comparative example.

FIG. 4 is a circuit diagram illustrating a voltage-current converter circuit according to a first embodiment of the invention.

FIG. 5 is a plot illustrating voltage-current characteristics of the voltage-current converter circuit according to the first embodiment of the invention.

FIG. 6 is a circuit diagram illustrating a voltage-current converter circuit according to a second embodiment of the invention.

FIG. 7 is a plot illustrating voltage-current characteristics of the voltage-current converter circuit according to the second embodiment of the invention.

FIG. 8 is a circuit diagram illustrating a PLL circuit having the voltage-current converter circuit according to a third embodiment of the invention.

FIG. 9 is a plot illustrating the control voltage-frequency characteristics of the VCO in the PLL circuit according to the third embodiment of the invention.

### DETAILED DESCRIPTION

According to an embodiment, a voltage-current converter circuit includes a first current mirror circuit, a first transistor, a variable resistor, a second transistor and a first current output unit. The first current mirror circuit includes a first conductivity type transistor supplied with a first voltage, and the first current mirror circuit is configured to produce a second electric current based on a first electric current. The first transistor has a second conductivity type, and the first electric current flows through the first transistor. One end of the variable resistor is connected to a source of the first transistor, the other end of the variable resistor is supplied with a second voltage, and a resistance value of the variable resistor changes depending on an input control voltage. The second transistor has the second conductivity type, and the second electric current flows through the second transistor. A drain and a gate of the second transistor are connected to the gate of the first transistor, and a source of the second transistor is supplied with the second voltage. The second transistor is configured such that a ratio W/L, a ratio of a gate width W to a gate length L, is smaller than a ratio W/L of the first transistor. The first current output unit is configured to output an output current based on the first electric current or the second electric current.

A voltage-current converter circuit and a GM-constant bias circuit according to a comparative example known to the inventors will now be described before embodiments of the present invention are described.

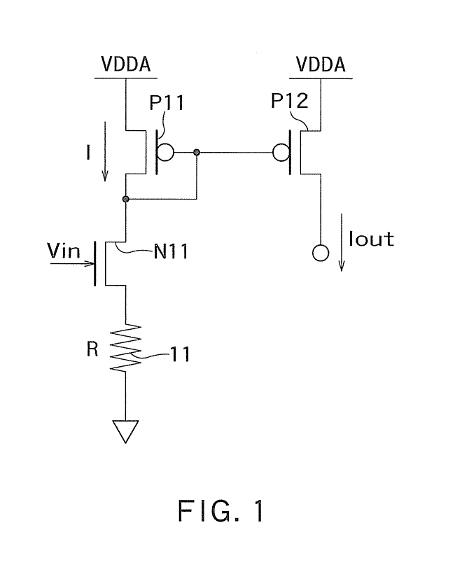

FIG. 1 is a circuit diagram illustrating a voltage-current converter circuit according to a comparative example.

Referring to FIG. 1, each of sources of the PMOS transistors P11 and P12 is supplied with a power supply voltage VDDA. The gate and the drain of the PMOS transistor P11 are connected to the gate of the PMOS transistor P12 and the drain of the NMOS transistor N11. A control voltage Vin is input to the gate of the NMOS transistor N11. The resistor 11 is connected between the source of the NMOS transistor N11 and the ground voltage. An output current Iout is output from the drain of the PMOS transistor P12.

The NMOS transistor N11 is turned on when the control voltage Vin reaches its threshold value Vth or higher. As a result, the electric current I flows to the PMOS transistor P11, the NMOS transistor N11, and the resistor 11. The PMOS transistors P11 and P12 output the output current Tout by mirroring the electric current I. In addition, the electric current I is controlled by changing the resistance value of the NMOS transistor N11 in response to the control voltage Vin. Therefore, the output current Tout is also controlled in response to the control voltage Vin.

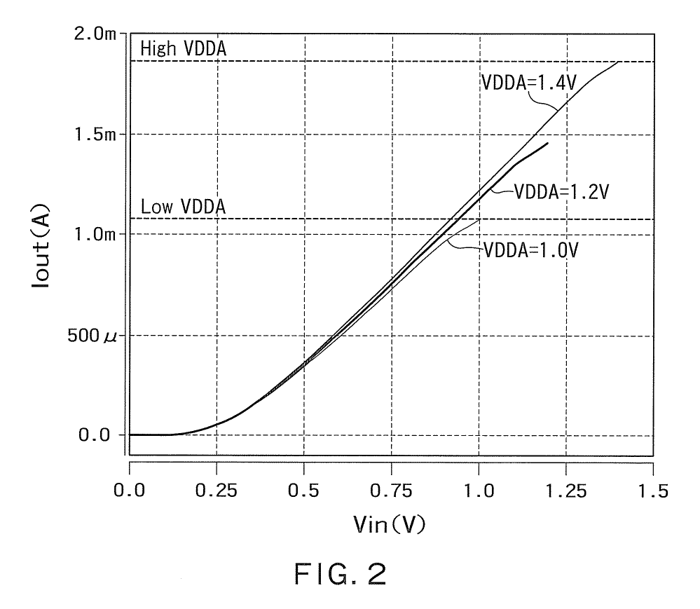

FIG. 2 is a plot illustrating voltage-current characteristics of the voltage-current converter circuit according to the comparative example.

In FIG. 2, the abscissa refers to the control voltage Vin, and the ordinate refers to the output current Iout. FIG. 2 exemplarily illustrates a voltage-current characteristic at a low power supply voltage (VDDA=1.0V), a voltage-current characteristic at an intermediate power supply voltage (VDDA=1.2V), and a voltage-current characteristic at a high power supply voltage (VDDA=1.4V). In addition, the characteristics at a low power supply voltage and at a high power supply voltage correspond to process conditions under which worst characteristics are obtained at each power supply voltage.

In this circuit, for example, if the control voltage Vin is set to 1.0 V or higher when the power supply voltage increases from 1.0 V to 1.4 V, the resistance value of the NMOS transistor N11 is reduced in comparison with the case where the power supply voltage is set to 1.0 V. For this reason, the electric current increases, and the output current Iout also increases. In other words, the maximum value of the output current Tout obtained when the control voltage Vin is equal to the power supply voltage remarkably changes depending on the power supply voltage.

Next, a GM-constant bias circuit will be described.

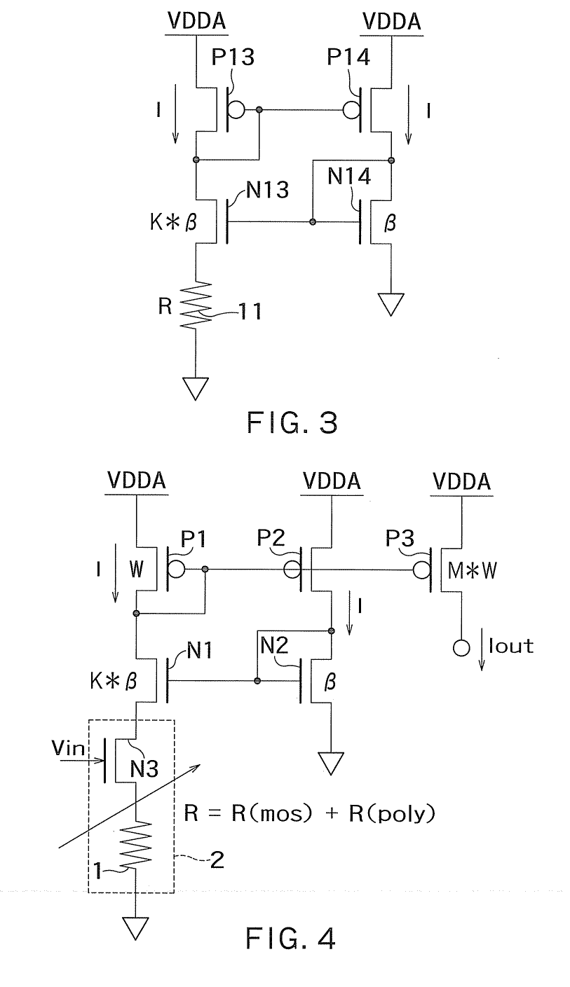

FIG. 3 is a circuit diagram illustrating a GM-constant bias circuit in a comparative example.

Referring to FIG. 3, each of sources of the PMOS transistors P13 and P14 is supplied with the power supply voltage VDDA. The gate and drain of the PMOS transistor P13 are connected to the drain of the NMOS transistor N13 and the gate of the PMOS transistor P14. The resistor 11 is connected between the source of the NMOS transistor N13 and the ground voltage. The gate of the NMOS transistor N13 is connected to the drain and gate of the NMOS transistor N14 and the drain of the PMOS transistor P14. The source of the NMOS transistor N14 is supplied with the ground voltage. The size of the NMOS transistor N13 (gate width W/gate length L) is K times the size of the NMOS transistor N14.

PMOS transistors P13 and P14 serve as a current mirror, so that the electric current I flowing to the PMOS transistor P13 is copied and thus the same electric current I flows to the PMOS transistor P14. Therefore, the operation point of this circuit is determined in a manner such that the electric current I flowing through the PMOS transistor P13, the NMOS transistor N13, and the resistor 11 becomes equal to the electric current I flowing through the PMOS transistor P14 and the NMOS transistor N14.

In this case, the electric current I can be approximated to Equation (1) as follows:

$$I = \frac{2}{β {R}^{2}} {( 1 - \frac{1}{\sqrt{K}} )}^{2} \qquad ( 1 )$$

where, β=(1/2)μCₒₓ(W/L), W denotes the gate width, L denotes the gate length, μ denotes mobility, Cₒₓ denotes a capacity of a gate oxide film per unit area, and these are physical properties of the NMOS transistor N14. In addition, R denotes the resistance value of the resistor 11. In addition, it is assumed in Equation (1) that the output resistance of each transistor is infinite.

As recognized from Equation (1), the electric current I becomes a constant value determined by the constants β, R, and K. In practice, since the output resistance of each transistor is finite but sufficiently large, the electric current I is little affected by variation in the power supply voltage or variation in the process conditions. In other words, even when the power supply voltage changes, the electric current I and the trans-conductance gm of the NMOS transistor becomes nearly constant.

Hereinafter, embodiments of the invention will be described with reference to the accompanying drawings. The present invention is not limited to the embodiments.

### First Embodiment

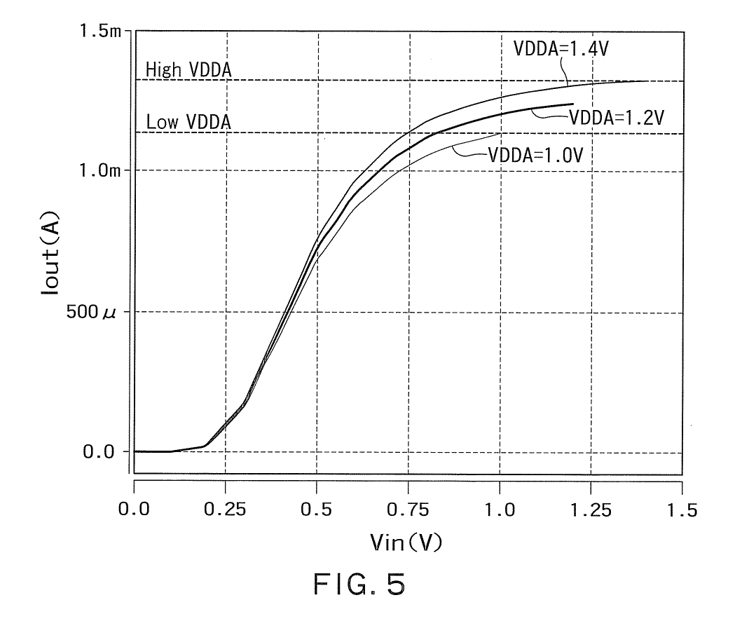

A first embodiment of the invention will now be described with reference to FIGS. 4 and 5. In the present embodiment, the resistance value used to determine the electric current value of the GM-constant bias circuit is controlled by the control voltage.

FIG. 4 is a circuit diagram illustrating a voltage-current converter circuit according to the first embodiment of the invention.

Referring to FIG. 4, the voltage-current converter circuit includes a PMOS transistor P1 (fourth transistor), a PMOS transistor P2 (fifth transistor), a PMOS transistor P3 (sixth transistor), an NMOS transistor N1 (first transistor), an NMOS transistor N2 (second transistor), an NMOS transistor N3 (third transistor), and a resistor 1 (first resistor). In this embodiment, a first conductivity type is set to a P-type, and a second conductivity type is set to an N-type. The gate widths of the PMOS transistors P1 and P2 are equal to each other. The gate width of the PMOS transistor P3 is M-times the gate width of the PMOS transistor P1. The gate width of the NMOS transistor N1 is K-times the gate width of the NMOS transistor N2 (where, K>1). The gate lengths of the PMOS transistors P1, P2, and P3 are equal to one another, and the gate lengths of the NMOS transistors N1 and N2 are equal to each other. In other words, the ratio W/L, the ratio of the gate width W to the gate length L, of the NMOS transistor N2 is smaller than the ratio W/L of the NMOS transistor N1.

Each source of the PMOS transistors P1, P2, and P3 is supplied with the power supply voltage VDDA (first voltage). The gate and drain of the PMOS transistor P1 are connected to the drain of the NMOS transistor N1 and each gate of the PMOS transistors P2 and P3. The source of the NMOS transistor N1 is connected to the drain of the NMOS transistor N3. The control voltage Vin is input to the gate of the NMOS transistor N3. One end of the resistor 1 is connected to the source of the NMOS transistor N3, and the other end thereof is supplied with a ground voltage (second voltage). The gate of the NMOS transistor N1 is connected to the drain and gate of the NMOS transistor N2 and the drain of the PMOS transistor P2. The source of the NMOS transistor N2 is supplied with the ground voltage. The drain of the PMOS transistor P3 outputs the electric current Iout to the load (not shown).

The NMOS transistor N3 and the resistor 1 form a variable resistor 2 having a resistance value that changes in response to the input control voltage Vin. The resistance value R of the variable resistor 2 is the sum of the resistance value R(mos) of the NMOS transistor N3 and the resistance value R(poly) of the resistor 1. That is, it can be expressed as R=R(mos)+R(poly).

In the PMOS transistors P1 and P2 serving as a first current mirror circuit, the same electric current I (second electric current) as the electric current I (first electric current), which is a reference current flowing to the PMOS transistor P1, flows to the PMOS transistor P2. Therefore, the operation point of the voltage-current converter circuit is determined in such a manner that the electric current I flowing through the PMOS transistor P1, the NMOS transistors N1 and N3, and the resistor 1 becomes equal to the electric current I flowing through the PMOS transistor P2 and the NMOS transistor N2.

In addition, the voltage V_{GSN2} between the gate and source of the NMOS transistor N2 is larger than the voltage V_{GSN1} between the gate and source of the NMOS transistor N1, and can be expressed as V_{GSN2}=V_{GSN1}+RI.

In addition, the PMOS transistor P3 (first current output unit) multiplies the electric current I flowing to the PMOS transistor P1 by M and outputs the output current Iout.

Based on such a relationship, the output current Iout is approximated to Equation (2) as follows:

$$I out = \frac{2 M}{β {R}^{2}} {( 1 - \frac{1}{\sqrt{K}} )}^{2} \qquad ( 2 )$$

As described above, the reference symbol β is determined by the physical properties of the NMOS transistor N2. In addition, it is assumed that the output resistance of each transistor is infinite.

As recognized from Equation (2), the output current Iout is determined only by the constants β, K, and M and the resistance value R which is a variable. In practice, since the output resistance of each transistor is finite but sufficiently large, the output current Tout is little affected by a variation in the power supply voltage or a variation in the process condition.

Here, the resistance value R(mos) changes depending on the control voltage Vin. Since the resistance value R(poly) is constant, the resistance value R changes depending on the control voltage Vin. Therefore, the output current Iout is controlled by the control voltage Vin according to Equation (2).

When the control voltage Vin is equal to or higher than a predetermined voltage, the resistance value R(poly) becomes nearly zero, and the resistance value R becomes substantially constant. Therefore, the output current Iout becomes substantially constant according to Equation (2).

FIG. 5 is a plot illustrating voltage-current characteristics of the voltage-current converter circuit according to a first embodiment of the invention.

In FIG. 5, the abscissa denotes the control voltage Vin, and the ordinate denotes the output current Iout. FIG. 5 exemplarily illustrates a voltage-current characteristic at a low power supply voltage (VDDA=1.0V), a voltage-current characteristic at an intermediate power supply voltage (VDDA=1.2V), and a voltage-current characteristic at a high power supply voltage (VDDA=1.4V). In addition, the process conditions of each characteristic are similar to those of the comparative example.

As recognized from such voltage-current characteristics, in a range of the control voltage Vin from about 0.2 V to about 0.6 V, a nearly linear characteristic is exhibited as in the characteristics of the voltage-current converter circuit of the comparative example of FIG. 2. That is, in this range, the resistance value R is variable.

The reason of the substantial linear characteristic is that, although the electric current I flowing from the NMOS transistor N3 increases in proportion to the square of the voltage between the gate and source thereof when the control voltage Vin increases, the voltage at one end of the resistor 1, across which the electric current I flows, increases, and thus the operation point is determined so that the gate-source voltage of the NMOS transistor N3 may be reduced.

In a range of the control voltage Vin higher than about 0.6 V, the characteristic close to that of the GM-constant bias circuit of the comparative example of FIG. 3 is exhibited (the output current Iout does not depend on the control voltage Vin, and the output current Iout less depends on the power supply voltage). In other words, in this range, the resistance value R becomes substantially constant.

In this manner, as compared with the voltage-current characteristics of the voltage-current converter circuit of the comparative example of FIG. 2, dependence of the maximum value of the output current Iout on the power supply voltage is reduced to about ⅓. However, this value of ⅓ may change to other values less than one, in accordance with design of the voltage-current converter circuit.

As described above, according to the present embodiment, the resistance value for determining the electric current of the GM-constant bias circuit is controlled by the control voltage Vin. Therefore, it is possible to change the output current Iout based on the control voltage Vin, and reduce dependence of the maximum value of the output current Iout on the power supply voltage in comparison with the comparative example.

### Second Embodiment

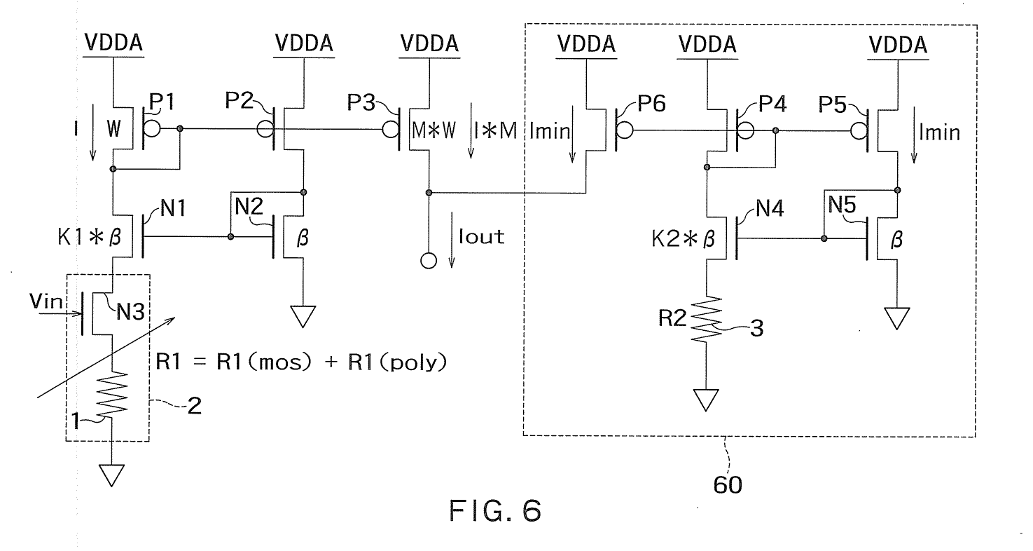

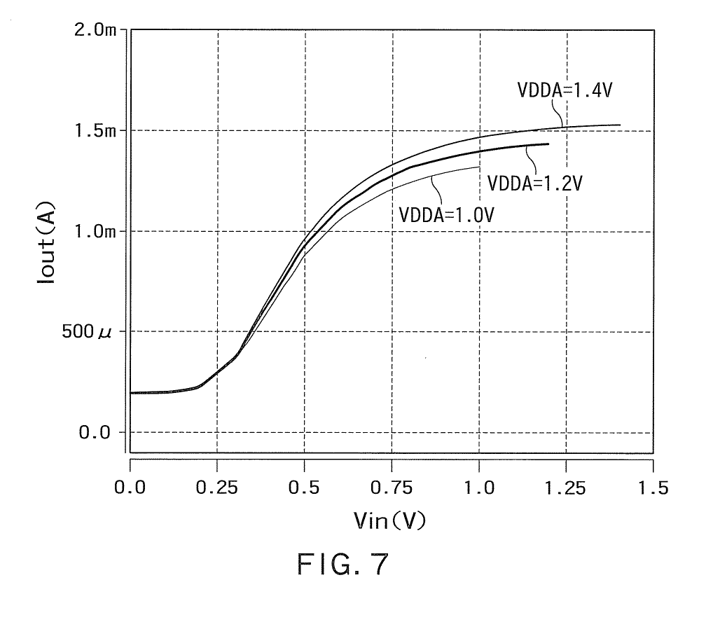

A second embodiment of the invention will now be described with reference to FIGS. 6 and 7. The present embodiment is different from the first embodiment in that a constant electric current that is independent of the power supply voltage is added to the output current.

FIG. 6 is a circuit diagram illustrating a voltage-current converter circuit according to a second embodiment of the invention.

The voltage-current converter circuit further includes a GM-constant bias circuit 60 similar to that of the comparative example of FIG. 3 in addition to the voltage-current converter circuit of the first embodiment of FIG. 4.

The GM-constant bias circuit 60 includes a PMOS transistor P4 (ninth transistor), a PMOS transistor P5 (tenth transistor), a PMOS transistor P6 (eleventh transistor), an NMOS transistor N4 (seventh transistor), an NMOS transistor N5 (eighth transistor), and a resistor 3 (second resistor). The sizes (W/L) of the PMOS transistors P4, P5, and P6 are equal to one another. The gate width of the NMOS transistor N4 is K2 times the gate width of the NMOS transistor N5 (where, K2>1). The gate lengths of the NMOS transistors N4 and N5 are equal to each other. That is, a ratio W/L, the ratio of the gate width W to the gate length L, of the NMOS transistor N5 is smaller than the ratio W/L of the NMOS transistor N4.

Each source of the PMOS transistors P4, P5, and P6 is supplied with the power supply voltage VDDA. The gate and drain of the PMOS transistor P4 are connected to the drain of the NMOS transistor N4 and each gate of the PMOS transistors P5 and P6. One end of the resistor 3 is connected to the source of the NMOS transistor N4, and the other end is supplied with the ground voltage. The gate of the NMOS transistor N4 is connected to the drain and gate of the NMOS transistor N5 and the drain of the PMOS transistor P5. The source of the NMOS transistor N5 is supplied with the ground voltage. The drain of the PMOS transistor P6 is connected to the drain of the PMOS transistor P3. Since other circuit configurations are similar to those of the first embodiment of FIG. 4, like reference numerals denote like elements, and description thereof will not be repeated. In addition, in the present embodiment, the first conductivity type is set to a P-type, and the second conductivity type is set to an N-type.

Similar to the comparative example, in the PMOS transistors P4 and P5 serving as the second current mirror circuit, the electric current Imin (fourth electric current), which is the same as the electric current Imin (third electric current) serving as a reference current flowing to the PMOS transistor P4, flows to the PMOS transistor P5. Therefore, the operation point of the GM-constant bias circuit 60 is determined so that the electric current Imin flowing through the PMOS transistor P4, the NMOS transistor N4, and the resistor 3 may be equal to the electric current Imin flowing through the PMOS transistor P5 and the NMOS transistor N5. In addition, the PMOS transistor P6 (second current output unit) outputs the same electric current as the electric current Imin flowing through the PMOS transistor P4. As a result, as described with reference to the comparative example, the GM-constant bias circuit 60 produces a constant electric current Imin that little depends on the power supply voltage. The output current Iout becomes the sum of the electric current IxM coming from the voltage-current converter circuit of the first embodiment and the electric current Imin coming from the GM-constant bias circuit 60 and is expressed as Equation (3) as follows:

$$Iout = \frac{2 M}{β R {1}^{2}} {( 1 - \frac{1}{\sqrt{K 1}} )}^{2} + \frac{2}{β R {2}^{2}} {( 1 - \frac{1}{\sqrt{K 2}} )}^{2} \qquad ( 3 )$$

wherein, R1 denotes the resistance value of the variable resistor 2, R1(mos) denotes the resistance value of the NMOS transistor N3, R1(poly) denotes the resistance value of the resistor 1, and R2 denotes the resistance value of the resistor 3. In addition, the size of the NMOS transistor N1 is set to K1 times the size of the NMOS transistor N2 (where, K1>1).

In Equation (3), the first term is similar to Equation (2) of the first embodiment, and the second term is similar to Equation (1) of the comparative example. In other words, the first term changes depending on the control voltage Vin, whereas the second term is constant instead of depending on the control voltage Vin. Therefore, when the control voltage Vin is lower than the threshold value Vth of the NMOS transistor N3, the output current Iout becomes a constant value determined by the second term.

FIG. 7 is a plot illustrating voltage-current characteristics of the voltage-current converter circuit according to a second embodiment of the invention.

FIG. 7 illustrates a voltage-current characteristic at a low power supply voltage (VDDA=1.0V), a voltage-current characteristic at an intermediate power supply voltage (VDDA=1.2V), and a voltage-current characteristic at a high power supply voltage (VDDA=1.4V). In addition, the process conditions of each characteristic are similar to those of the first embodiment.

As recognized from such voltage-current characteristics, in a range of the control voltage Vin close to the power supply voltage, similar to the voltage-current characteristics of the first embodiment of FIG. 5, dependence of the maximum value of the output current Iout on the power supply voltage is insignificant. In a range of the control voltage Vin lower than a threshold value, the output current Tout becomes a minimum value and little depends on the power supply voltage.

As described above, according to the present embodiment, a constant electric current that little depends on the power supply voltage is added to the output current of the voltage-current converter circuit of the first embodiment. Therefore, it is possible to flow the output current Iout that little depends on the power supply voltage even when the control voltage Vin is low, and the output current of the voltage-current converter circuit of the first embodiment does not flow.

In addition, similar to the first embodiment, it is possible to reduce dependence of the maximum value of the output current Iout on the power supply voltage in comparison with the comparative example.

### Third Embodiment

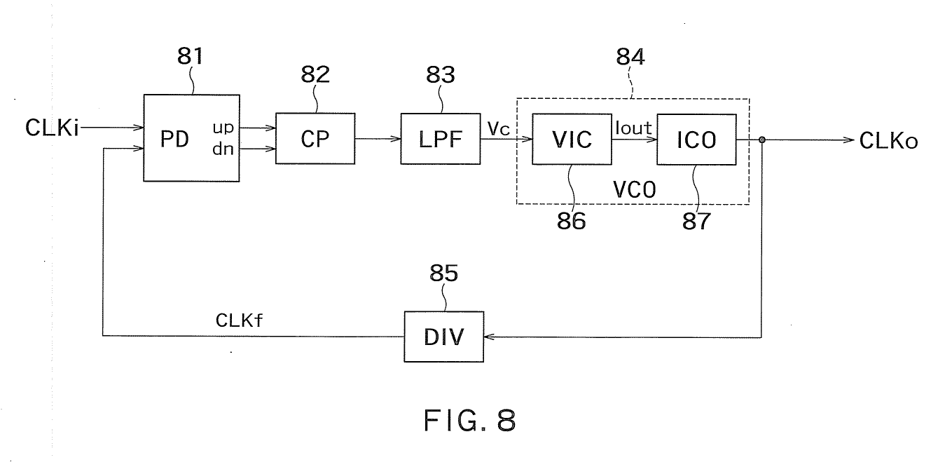

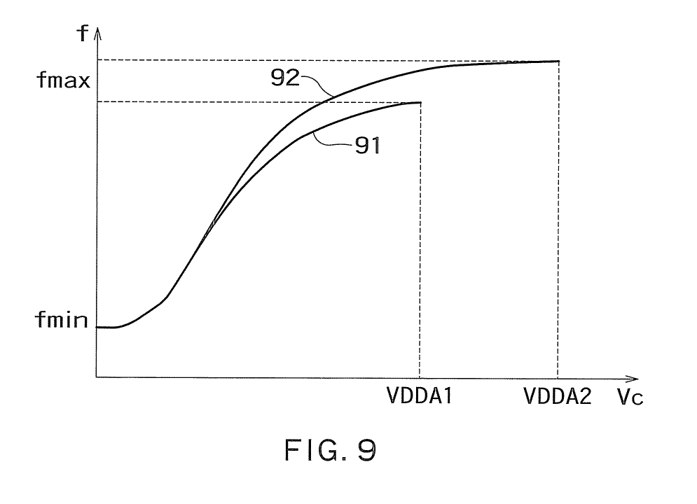

A third embodiment of the invention will now be described with reference to FIGS. 8 and 9. In the present embodiment, a PLL circuit is configured using the voltage-current converter circuit of the second embodiment.

FIG. 8 is a circuit diagram illustrating a PLL circuit having the voltage-current converter circuit according to a third embodiment of the invention.

This PLL circuit includes a phase comparator (PD) 81, a charge pump (CP) 82, a low-pass filter (LPF) 83, a voltage controlled oscillator (hereinafter, referred to as VCO) 84, and a divider (DIV) 85. The VCO 84 has a voltage-current converter circuit (VIC) 86 and a current controlled oscillator (ICO) 87. The voltage-current converter circuit 86 is the voltage-current converter circuit of the second embodiment. The current controlled oscillator 87 is configured of, for example, a ring oscillator.

The phase comparator 81 compares a phase of the input clock (reference clock) CLKi and a phase of the feedback clock CLKf and outputs the output signals up and dn depending on the phase difference. The charge pump 82 converts the output signals up and do from the phase comparator 81 into the electric currents. The low-pass filter 83 converts the electric current from the charge pump 82 into the control voltage Vc. The voltage-current converter circuit 86 converts the control voltage Vc from the low-pass filter 83 into the output current Iout. In addition, the control voltage Vc corresponds to the control voltage Vin of the first and second embodiments. The current controlled oscillator 87 outputs the output clock CLKo having a frequency corresponding to the output current Iout from the voltage-current converter circuit 86. The divider 85 divides the output clock CLKo from the current controlled oscillator 87 and outputs the feedback clock CLKf to the phase comparator 81.

As a result, the PLL circuit is locked by controlling the oscillation frequency of the current controlled oscillator 87, such that the frequency of the input clock CLKi becomes equal to the frequency of the feedback clock CLKf, to output the output clock CLKo having a desired frequency.

FIG. 9 is a plot illustrating the control voltage-frequency characteristics of the VCO in the PLL circuit according to a third embodiment of the invention.

In FIG. 9, the abscissa denotes the control voltage Vc, and the ordinate denotes the oscillation frequency f. The control voltage-frequency characteristic 91 shows the characteristic at a low power supply voltage VDDA1, and the characteristic 92 shows the characteristic at a high power supply voltage VDDA2.

As described above, in the voltage-current converter circuit of the second embodiment, dependence of the maximum value of the output current Iout on the power supply voltage is reduced to about ⅓ in comparison with the comparative example. In addition, the minimum value of the output current Iout little depends on the power supply voltage. Therefore, in the current controlled oscillator 87 in which the oscillation frequency f changes depending on the output current Iout, dependence of the maximum oscillation frequency fmax on the power supply voltage is reduced to about ⅓ in comparison with a case where the voltage-current converter circuit of the comparative example is used. In addition, even when the control voltage Vc becomes lower than a threshold value, it is possible to oscillate at a minimum oscillation frequency fmin which little depends on the power supply voltage.

As described above, according to the present embodiment, the circuit of the second embodiment in which dependence of maximum and minimum values of the output current on the power supply voltage is insignificant is used in the voltage-current converter circuit 86 of the VCO 84. Therefore, it is possible to reduce dependence of the maximum oscillation frequency fmax and the minimum oscillation frequency fmin of the VCO 84 on the power supply voltage. As a result, even when the power supply voltage changes, the VCO 84 can oscillate across the entire frequency range of a specification without significantly exceeding therefrom. Therefore, the divider 85 which receives the oscillation signal of the VCO 84 can operate normally, and the PLL circuit can be locked at the frequency range of a specification.

In addition, the voltage-current converter circuit of the first embodiment may be used as the voltage-current converter circuit 86 in the VCO 84. Even in this case, dependence of the maximum oscillation frequency fmax on the power supply voltage is reduced to about ⅓ in comparison with a case where the voltage-current converter circuit of the comparative example is used.

While embodiments of the invention have been described hereinbefore, a detailed configuration is not limited to the aforementioned embodiments, and may be variously modified and implemented without departing from the spirit of the invention.

For example, in the first and second embodiments, the output current may be output based on the electric current I flowing to the NMOS transistor N2 using the NMOS transistor (first current output unit) in which the gate is connected to each gate of the NMOS transistors N1 and N2 and the source is supplied with the ground voltage.

In addition, the voltage-current converter circuit of the first and second embodiments may be applied to various fields other than the PLL circuit.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A voltage-current converter circuit comprising:
a first current mirror circuit comprising a first conductivity type transistor supplied with a first voltage, the first current mirror circuit being configured to produce a second electric current based on a first electric current;
a first transistor having a second conductivity type, the first electric current flowing through the first transistor;
a variable resistor, one end of the variable resistor being connected to a source of the first transistor, the other end of the variable resistor being supplied with a second voltage, and a resistance value of the variable resistor changing depending on an input control voltage;
a second transistor having the second conductivity type, the second electric current flowing through the second transistor, a drain and a gate of the second transistor being connected to the gate of the first transistor, a source of the second transistor being supplied with the second voltage, the second transistor being configured such that a ratio W/L, a ratio of a gate width W to a gate length L, is smaller than a ratio W/L of the first transistor; and
a first current output unit configured to output an output current based on the first electric current or the second electric current.

2. The voltage-current converter circuit according to claim 1,
wherein the variable resistor comprises:
a third transistor having the second conductivity type, a drain of the third transistor being connected to the source of the first transistor, and a gate of the third transistor receiving the control voltage; and
a first resistor, one end of the first resistor being connected to a source of the third transistor, and the other end of the first resistor being supplied with the second voltage.

3. The voltage-current converter circuit according to claim 1,
wherein the first current mirror circuit comprises:
a fourth transistor having a first conductivity type, a source of the fourth transistor being supplied with the first voltage, and a drain and a gate of the fourth transistor being connected to a drain of the first transistor; and
a fifth transistor having the first conductivity type, a source of the fifth transistor being supplied with the first voltage, a gate of the fifth transistor being connected to the gate of the fourth transistor, and a drain of the fifth transistor being connected to the drain of the second transistor.

4. The voltage-current converter circuit according to claim 3,
wherein a gate width of the fourth transistor is equal to a gate width of the fifth transistor, and a gate length of the fourth transistor is equal to a gate length of the fifth transistor.

5. The voltage-current converter circuit according to claim 3,
wherein the first current output unit comprises a sixth transistor having the first conductivity type, a source of the sixth transistor being supplied with the first voltage, a gate of the sixth transistor being connected to the gate of the fourth transistor, and the output current flowing between the source and a drain of the sixth transistor.

6. The voltage-current converter circuit according to claim 1,
wherein the first electric current is equal to the second electric current.

7. The voltage-current converter circuit according to claim 1,
wherein the first conductivity type is a P-type, the second conductivity type is an N-type, the first voltage is a power supply voltage, and the second voltage is a ground voltage.

8. The voltage-current converter circuit according to claim 1, further comprising:
a bias circuit configured to generate a constant electric current and add the constant electric current to the output current, the constant electric current being independent of the first voltage and the second voltage.

9. The voltage-current converter circuit according to claim 8,
wherein the bias circuit comprises:
a second current mirror circuit comprising a first conductivity type transistor supplied with the first voltage, the second current mirror circuit being configured to produce a fourth electric current based on a third electric current;
a seventh transistor having the second conductivity type, the third electric current flows through the seventh transistor;
a second resistor, one end of the second resistor being connected to a source of the seventh transistor, and the other end of the second resistor being supplied with the second voltage;
an eighth transistor having the second conductivity type, the fourth electric current flowing through the eighth transistor, a drain and a gate of the eighth transistor being connected to a gate of the seventh transistor, a source of the eighth transistor being supplied with the second voltage, the eighth transistor being configured such that a ratio W/L, a ratio of a gate width W to a gate length L, is smaller than a ratio W/L of the seventh transistor; and
a second current output unit configured to output the constant electric current based on the third electric current or the fourth electric current.

10. The voltage-current converter circuit according to claim 9,
wherein the second current mirror circuit comprises:
a ninth transistor having the first conductivity type, a source of the ninth transistor being supplied with the first voltage, and a drain and a gate of the ninth transistor being connected to a drain of the seventh transistor; and
a tenth transistor having the first conductivity type, a source of the tenth transistor being supplied with the first voltage, a gate of the tenth transistor being connected to the gate of the ninth transistor, and a drain of the tenth transistor being connected to the drain of the eighth transistor.

11. The voltage-current converter circuit according to claim 10,
wherein a gate width of the ninth transistor is equal to a gate width of the tenth transistor, and a gate length of the ninth transistor is equal to a gate length of the tenth transistor.

12. The voltage-current converter circuit according to claim 10,
wherein the second current output unit comprises a eleventh transistor having the first conductivity type, a source of the eleventh transistor being supplied with the first voltage, a gate of the eleventh transistor being connected to the gate of the ninth transistor, and the constant electric current flowing between the source and a drain of the eleventh transistor.

13. The voltage-current converter circuit according to claim 12,
wherein the first current mirror circuit comprises:
a fourth transistor having the first conductivity type, a source of the fourth transistor being supplied with the first voltage, and a drain and a gate of the fourth transistor being connected to a drain of the first transistor; and
a fifth transistor having the first conductivity type, a source of the fifth transistor being supplied with the first voltage, a gate of the fifth transistor being connected to the gate of the fourth transistor, and a drain of the fifth transistor being connected to the drain of the second transistor, and
wherein the first current output unit comprises a sixth transistor having the first conductivity type, a source of the sixth transistor being supplied with the first voltage, a gate of the sixth transistor being connected to the gate of the fourth transistor, and the output current flowing between the source and a drain of the sixth transistor, and
wherein the drain of the eleventh transistor of the second current output unit is connected to the drain of the sixth transistor of the first current output unit.

14. The voltage-current converter circuit according to claim 9,
wherein the third electric current is equal to the fourth electric current.

15. The voltage-current converter circuit according to claim 9,
wherein the first conductivity type is a P-type, the second conductivity type is an N-type, the first voltage is a power supply voltage, and the second voltage is a ground voltage.

16. A phase-locked loop (PLL) circuit comprising:
a phase comparator configured to compare a phase of a reference clock and a phase of a feedback clock to output an output signal depending on a phase difference;
a charge pump configured to convert the output signal from the phase comparator into an electric current;
a low-pass filter configured to convert the electric current from the charge pump into a control voltage;
the voltage-current converter circuit according to claim 1, configured to convert the control voltage from the low-pass filter into the output current;
an oscillator configured to output an output clock having a frequency depending on the output current from the voltage-current converter circuit; and
a divider configured to output, to the phase comparator, the feedback clock obtained by dividing the output clock from the oscillator.

17. A phase-locked loop (PLL) circuit comprising:
a phase comparator configured to compare a phase of a reference clock and a phase of a feedback clock to output an output signal depending on a phase difference;
a charge pump configured to convert the output signal from the phase comparator into an electric current;
a low-pass filter configured to convert the electric current from the charge pump into a control voltage;
the voltage-current converter circuit according to claim 8, configured to convert the control voltage from the low-pass filter into the output current;
an oscillator configured to output an output clock having a frequency depending on the output current from the voltage-current converter circuit; and
a divider configured to output, to the phase comparator, the feedback clock obtained by dividing the output clock from the oscillator.
